(19) United States
(12) Patent Application Publication
(10) Pub. No.: US 2016/0178866 A1
(43) Pub. Date: Jun. 23, 2016

(54) OPTICAL MODULE AND OPTICAL MODULE LENS CAP

(71) Applicant: Mitsubishi Electric Corporation, Tokyo (JP)

(72) Inventors: Akihiro Matsusue, Tokyo (JP); Koichi Nakamura, Tokyo (JP); Hidekazu Kodera, Tokyo (JP)

(21) Appl. No.: 15/058,232

(22) Filed: Mar. 2, 2016

Related U.S. Application Data
(62) Division of application No. 14/277,100, filed on May 14, 2014.

(30) Foreign Application Priority Data
Sep. 27, 2013 (JP) 2013-201546

(51) Int. Cl. G02B 7/02; H01S 5/024; H01S 5/00

(52) U.S. Cl. CPC G02B 7/028; H01S 5/005; H01S 5/02415

(57) ABSTRACT

An optical module includes an optical module lens cap. The optical module lens cap is produced by press-molding a lens into a barrel. The barrel includes a cover portion and a cylindrical portion. The cover portion includes lens mounting holes. The cover portion includes a top surface and an undersurface that are mutually opposed. The undersurface faces the inside of the cylindrical portion. The barrel is Kovar. The lens is mounted in the lens mounting hole. A low melting point glass layer is located at a rim of the lens mounting hole in the barrel, filling a gap between the lens and the barrel.

### BACKGROUND OF THE INVENTION

1. Field of the Invention

The present invention relates to an optical module and an optical module lens cap.

2. Background Art

Conventionally, as disclosed, for example, in Japanese Patent Laid-Open No. 2007-93901, an optical module whose lens is press-molded into a barrel is known. In such an optical module whose lens is press-molded into a barrel, it is a general practice to select materials such that a linear expansion coefficient of the material of the barrel is larger than a linear expansion coefficient of the lens glass. This is because the lens is press-molded in a high temperature environment and a thermal caulking effect utilizing a difference in linear expansion coefficients is used in a subsequent cooling process. Airtightness between the lens and barrel is secured in this way.

However, the linear expansion coefficient of the material of the barrel cannot always be made larger than the linear expansion coefficient of the lens glass. Typically, since the barrel directly holds the lens, if the barrel thermally expands due to a change in ambient temperature, there is a problem that the lens position changes. When a material of a large linear expansion coefficient is used for the barrel, the distance from the barrel bottom surface to the lens fluctuates significantly due to a temperature change of the lens cap. If the distance between the lens and the light-emitting point of the semiconductor optical element changes, the laser condensing position of the lens fluctuates, resulting in a problem that optical output fluctuates.

To solve such problems, it is preferable to form a barrel using a material having a small linear expansion coefficient. As a metal material having a relatively small thermal expansion coefficient, for example, Kovar (registered trademark) is known which is an alloy of iron, nickel and cobalt. The optical module according to Japanese Patent Laid-Open No. 2007-93901 also uses Kovar for the barrel.

Other prior art includes Japanese Patent Laid-Open No. 2002-313973, Japanese Patent Laid-Open No. 2007-165551, Japanese Patent Laid-Open No. 5-55396, Japanese Patent Laid-Open No. 2010-27650, Japanese Patent Laid-Open No. 2005-191088, and Japanese Patent Laid-Open No. 2009-94179.

The lens glass should be selected in such a way that a refractive index of glass becomes high to some extent in order to increase coupling efficiency. Popular lens glass having a high refractive index has a tendency to have a relatively high linear expansion coefficient, and if an attempt is made to reduce the linear expansion coefficient of the material of the barrel, the linear expansion coefficient of the material of the barrel may be smaller than the linear expansion coefficient of the lens glass. If such a material is selected, the thermal caulking effect utilizing a difference in linear expansion coefficients is reduced, resulting in a problem that airtightness between the lens and the barrel decreases.

### SUMMARY OF THE INVENTION

The present invention has been implemented to solve the above-described problems and it is an object of the present invention to provide an optical module and an optical module lens cap capable of preventing deterioration of airtightness even when a press-molded lens has a larger linear expansion coefficient than that of a barrel.

According to a first aspect of the present invention, an optical module includes: a barrel, a lens, a glass layer, and a stem. The barrel is provided with a cylindrical portion and a cover portion provided at one end of the cylindrical portion, the cover portion is provided with a lens mounting hole, the other end of the cylindrical portion is left open, and the barrel is formed of a material having a first linear expansion coefficient. The lens is lens glass having a second linear expansion coefficient larger than the first linear expansion coefficient press-molded into the lens mounting hole. The glass layer is provided at a rim of the lens mounting hole of the barrel, fills a gap between the lens and the barrel and has a lower glass transition temperature than the lens glass. The stem includes a top surface and an optical element provided on the top surface, the optical element is covered with the barrel, the other end of the cylindrical portion of the barrel is bonded to the top surface.

According to a second aspect of the present invention, an optical module includes: a barrel, a lens, a flat glass, and a stem. The barrel is provided with a cylindrical portion and a cover portion provided at one end of the cylindrical portion, the cover portion is provided with a lens mounting hole, the other end of the cylindrical portion is left open, the barrel is formed of a material having a first linear expansion coefficient. The lens is lens glass having a second linear expansion coefficient larger than the first linear expansion coefficient press-molded into the lens mounting hole. The flat glass is provided at a rim of the lens mounting hole of the barrel and is connected via a glass layer having a lower glass transition temperature than the lens glass. The stem includes a top surface and an optical element provided on the top surface, the optical element is covered with the barrel, the other end of the cylindrical portion of the barrel is bonded to the top surface.

According to a third aspect of the present invention, an optical module lens cap includes: a barrel, a lens, and a glass layer. The barrel is provided with a cylindrical portion and a cover portion provided at one end of the cylindrical portion, the cover portion is provided with a lens mounting hole, the other end of the cylindrical portion is left open, and the barrel is formed of a material having a first linear expansion coefficient. The lens is lens glass having a second linear expansion coefficient larger than the first linear expansion coefficient press-molded into the lens mounting hole. The glass layer is provided at a rim of the lens mounting hole of the barrel, fills a gap between the lens and the barrel and has a lower glass transition temperature than the lens glass.

According to a fourth aspect of the present invention, an optical module lens cap includes: a barrel, a lens, a flat glass, and a stem. The barrel is provided with a cylindrical portion and a cover portion provided at one end of the cylindrical portion, the cover portion is provided with a lens mounting hole, the other end of the cylindrical portion is left open, the barrel is formed of a material having a first linear expansion coefficient. The lens is lens glass having a second linear expansion coefficient larger than the first linear expansion coefficient press-molded into the lens mounting hole. The flat glass is provided at a rim of the lens mounting hole of the barrel and is connected via a glass layer having a lower glass transition temperature than the lens glass.

Other and further objects, features and advantages of the invention will appear more fully from the following description.

### BRIEF DESCRIPTION OF THE DRAWINGS

FIG. 1 is a diagram illustrating an optical module according to a first embodiment of the present invention.

FIG. 2 is a cross-sectional view illustrating the optical module lens cap according to the first embodiment of the present invention.

FIG. 3 is a diagram illustrating an optical module lens cap according to a modification of the first embodiment of the present invention.

FIG. 4 is a cross-sectional view illustrating an optical module according to the modification of the first embodiment of the present invention.

FIG. 5 is a cross-sectional view illustrating the optical module lens cap according to the second embodiment of the present invention.

FIG. 6 is a cross-sectional view illustrating an optical module lens cap according to a modification of the second embodiment of the present invention.

FIG. 7 is a cross-sectional view illustrating an optical module according to a third embodiment of the present invention.

FIG. 8 is a cross-sectional view illustrating the optical module lens cap according to the third embodiment of the present invention.

FIG. 9 is a cross-sectional view illustrating an optical module lens cap according to a modification of the third embodiment of the present invention.

FIG. 10 is a graph used to describe operations and effects of the optical module according to the embodiment of the present invention.

### DETAILED DESCRIPTION OF THE PREFERRED EMBODIMENTS

### First Embodiment

### Configuration of Apparatus of First Embodiment

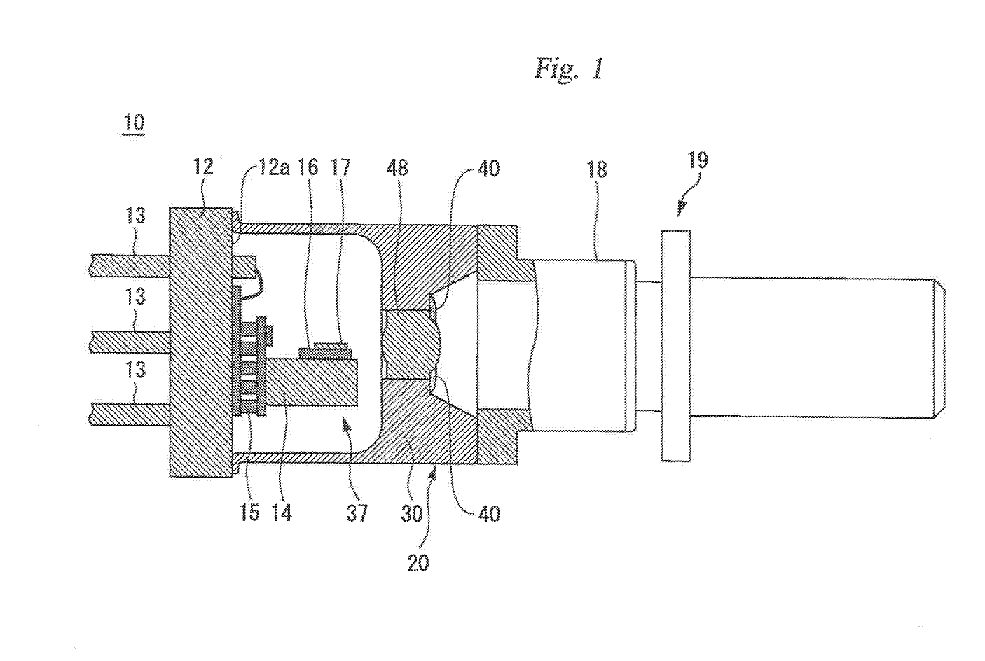

FIG. 1 is a diagram illustrating an optical module 10 according to a first embodiment of the present invention. The optical module 10 is provided with a stem 12, an optical module lens cap 20 that covers the stem 12, a receptacle holder 18 fixed to the lens cap 20 and a receptacle 19. Hereinafter, the optical module lens cap will be simply called “lens cap” for convenience of description.

The lens cap 20 is configured by press-molding a lens 48 into a barrel 30. The barrel 30 as a whole is cylindrical and a cavity 37 is formed therein. An inner surface of the barrel 30 and a top surface 12a of the stem 12 form the cavity.

A Peltier module 15 is provided on the top surface 12a of the stem 12. A metal block 14 is provided on the Peltier module 15. A submount 16 is provided on one side of the metal block 14 and a laser diode 17 which is an optical element is mounted on this submount 16. Although not shown in FIG. 1, electrodes of the laser diode 17 are connected to lead pins 13 via metal wire.

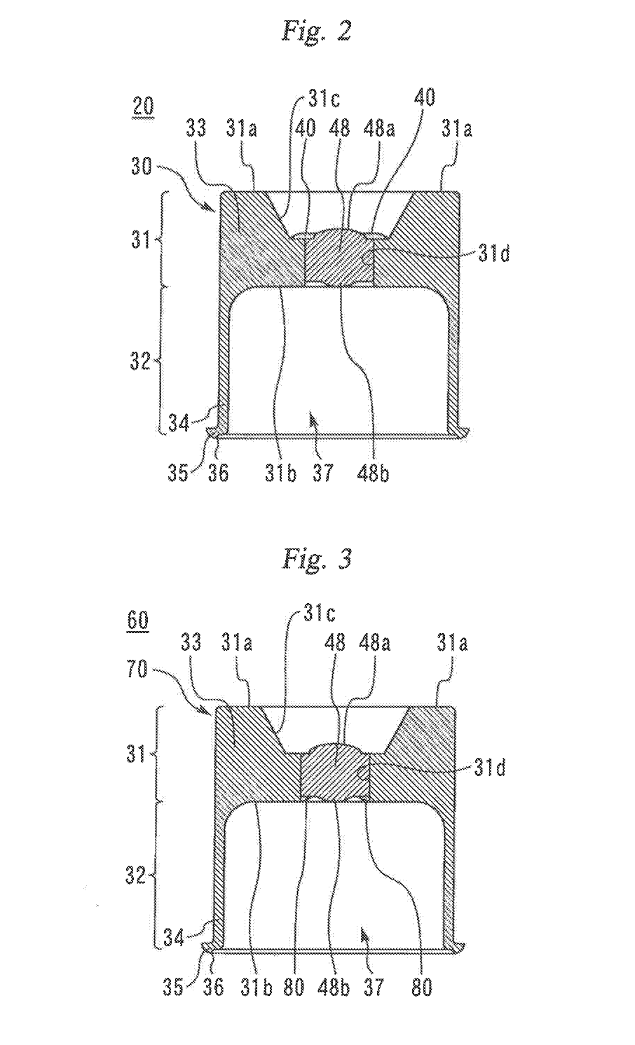

FIG. 2 is a cross-sectional view illustrating the optical module lens cap 20 according to the first embodiment of the present invention. The lens cap 20 is configured by press-molding the lens 48 into the barrel 30. The barrel 30 is provided with a cover portion 31 and a cylindrical portion 32.

The cover portion 31 is provided at one end of the cylindrical portion 32. The cover portion 31 is provided with a thick-walled portion 33 and lens mounting holes 31c and 31d provided at a center of the thick-walled portion 33. The cover portion 31 is provided with mutually opposed surfaces: a top surface 31a and an undersurface 31b, and the undersurface 31b faces an inside of the cylindrical portion 32. The lens mounting hole 31d is a circular hole having a certain diameter and the lens mounting hole 31c is a hole provided so as to gradually increase in diameter from one end of the lens mounting hole 31d toward the top surface 31a of the cover portion 31.

The barrel 30 is a metallic barrel made of an alloy of iron, cobalt and nickel, or more specifically Kovar (registered trademark). As the material of the barrel 30, 42Ni—Fe or the like can also be used. The linear expansion coefficient of Kovar is 4.9×10⁻⁶ [1/K] to 5.5×10⁻⁶ [1/K] and the linear expansion coefficient of Fe-42Ni is 4.5×10⁻⁶ [1/K] to 6×10⁻⁶ [1/K].

The cylindrical portion 32 is a cylindrical tube whose interior forms the cavity 37. A side wall 34 of the cylindrical portion 32 is thin and the cavity 37 is provided therein. The other end of the cylindrical portion 32 is left open and a collar portion 35 is provided at the other end. A bottom surface 36 of the collar portion 35 is fixed to the top surface 12a of the stem 12 and hermetically sealed.

The lens 48 is mounted in the lens mounting hole 31d. The lens 48 is provided by press-molding the lens glass into the lens mounting hole 31d. The lens glass having a high refractive index used here is, for example, L-LAH85 (having a linear expansion coefficient of 7.8×10⁻⁶ [1/K]).

A low melting point glass layer 40 is provided at a rim of the lens mounting hole 31c in the barrel 30, filling a gap between the lens and the barrel 30. The low melting point glass layer 40 is continuously provided from a surface of the lens 48 on the top surface 31a side to an inner surface of the lens mounting hole 31c in the cover portion 31. Though not shown, the low melting point glass layer 40 is provided in a ring shape in a plan view along a contacting portion between the lens 48 and the rim of the lens mounting hole 31d. A leak path can be covered in this way. The leak path refers to a clearance or crack generated on a joint interface between the lens and the barrel so as to extend from the surface side to the back side of the lens.

The low melting point glass layer 40 is glass having a lower glass transition temperature than the lens glass used for press molding of the lens 48. In the first embodiment, glass having a softening point of 600° C. or less is referred to as low melting point glass.

It is preferable to select low melting point glass having a linear expansion coefficient between the linear expansion coefficient of the barrel 30 and that of the press lens glass in order to reduce cracks caused by mismatch in the amount of heat deformation between the barrel 30 and the press lens glass. For example, in a combination of the barrel 30 formed of Kovar and the press molding lens glass formed of L-LAH85, the low melting point glass preferably has a linear expansion coefficient of 5.5×10⁻⁶ [1/K] to 7.5×10⁻⁶ [1/K]. For example, LS-2010 having a linear expansion coefficient of 6.5×10⁻⁶ [1/K] may be used as low melting point glass.

### [Operations and Effects of Apparatus of First Embodiment]

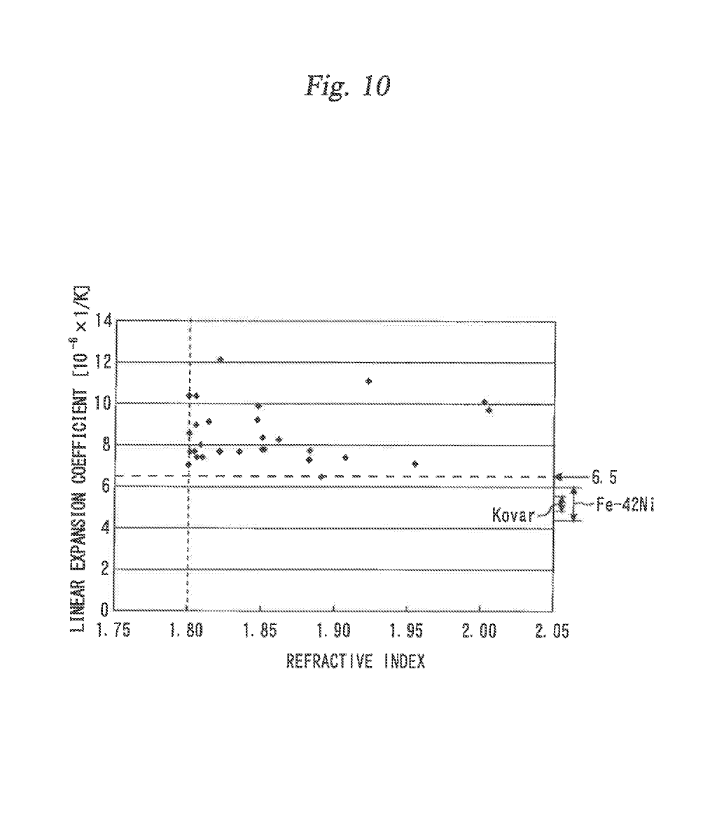

FIG. 10 is a graph used to describe operations and effects of the optical module 10 according to the embodiment of the present invention. FIG. 10 shows results of evaluating a relationship between a refractive index and a linear expansion coefficient of commercially available press lens glass. In order to realize high coupling efficiency, it is necessary to select a material having a high refractive index of, for example, 1.8 or more for the lens glass. As shown in FIG. 10, most of linear expansion coefficients of the press lens glass having a high refractive index are 6.5×10⁻⁶ [1/K] or more.

In FIG. 10, 4.9×10⁻⁶ [1/K] to 5.5×10⁻⁶ [1/K] which is a linear expansion coefficient of Kovar and 4.5×10⁻⁶ [1/K] to 6×10⁻⁶ [1/K] which is a linear expansion coefficient of Fe-42Ni are shown by arrows. As shown in FIG. 10, when lens glass having a high refractive index of 1.8 or more is adopted and at the same time Kovar is used for the barrel 30, the linear expansion coefficient of the lens glass is greater than the linear expansion coefficient of the barrel 30.

In this case, a force of thermal caulking between the barrel 30 and the lens 48 decreases and a leakage occurs. A leakage of 1.0×10⁻⁵ Pa·m³/s or more actually occurred with the lens cap 20 which uses press lens glass having a linear expansion coefficient of approximately 8×10⁻⁶/K for the Kovar barrel 30. For enhancement of moldability, lens glass for press molding with a reduced glass transition temperature Tg is available. An example is Ohara L-LAH series. This kind of glass has a higher linear expansion coefficient of 7.0×10⁻⁶ [1/K] or more, producing a greater leakage.

For the press lens glass, high priority needs to be given to optical characteristics such as moldability (molding temperature) of the lens shape and refractive index, and therefore a selection giving priority to only linear expansion coefficients is not possible. In contrast, since the low melting point glass layer 40 is intended for securing bonding and airtightness between the lens 48 and the barrel 30 and refractive indices need not be considered, the low melting point glass layer 40 can be freely selected from among materials having a variety of linear expansion coefficients.

Therefore, it is possible to approximate its linear expansion coefficient to a small linear expansion coefficient of a material such as Kovar or select an intermediate linear expansion coefficient between the lens glass and the barrel 30. Moreover, since a melting temperature lower than a press lens molding temperature can be selected, it is also possible to reduce thermal distortion accompanying the cooling after the melting of the low melting point glass. Filling the leak path between the lens 48 and the barrel 30 which occurs after the press molding of the lens 48 with the low melting point glass layer 40 provides a high advantage from the standpoint of securing airtightness.

By filling (covering) the leak path with the low melting point glass layer 40, it is possible to secure airtightness of the lens cap even when a material having a smaller linear expansion coefficient with respect to the lens glass having a high refractive index and a large linear expansion coefficient is applied to the barrel 30 or when the linear expansion coefficient of the press lens glass is higher than the linear expansion coefficient of the metal barrel (e.g., when the difference thereof is 3.0×10⁻⁶ [1/K] or more). For example, the present embodiment can secure high airtightness of 1×10⁻⁹ Pa·m³/s or less.

Since the lens is molded through pressing with a pressing apparatus, high lens position accuracy is achieved and the lens position with respect to the barrel during pressing is fixed, there is no need for tools or the like for determining the lens position when the low melting point glass is melted and productivity is also improved. Since the material having a low linear expansion coefficient is used for the barrel, it is possible to reduce a lens position variation caused by heat deformation to 0 to 3.0 um (ΔT=70.0 K).

In the above-described embodiment, the barrel is formed of a material having a linear expansion coefficient less than 6 5×10⁻⁶ [1/K], more specifically Kovar or Fe-42Ni, but the present invention is not limited to this. The barrel may also be formed of a material having a linear expansion coefficient greater than 6.5×10⁻⁶ [1/K]. For example, the present invention is also applicable to a case where a material such as SUS430 (linear expansion coefficient of 10×10⁻⁶ [1/K] to 11×10⁻⁶[1/K]) is used for the barrel with respect to the press lens glass having a high linear expansion coefficient (e.g., L-BBH manufactured by Ohara Inc., having a linear expansion coefficient of 13.0×10⁻⁶ [1/K] or more).

Since the low melting point glass layer 40 is used in the first embodiment in particular, it is possible to obtain the following glass-specific advantages.
A heat-proof temperature of solder or adhesive is 300° C. or less. It is 219° C. for general SnAgCu solder and 280° C. for AuSn solder which is high melting point solder. In contrast, glass has an advantage that its heat-proof temperature is high.
Since an adhesive allows water to pass therethrough, it cannot secure airtightness at a leakage rate of 1×10⁻⁹ Pam³/s or less. In contrast, since glass does not allow water/air or the like to pass therethrough, it has an advantage of being able to secure airtightness.
When solder is applied, a solder-wetting material needs to be used for the bonded surface. Since the lens is made of glass which is not a solder-wetting material, Au or the like needs to be applied through vapor deposition or plating. However, since vapor deposition or plating should not be applied to the portion through which light passes, it takes considerable time and effort. In contrast, low melting point glass has an advantage that no surface treatment such as plating is necessary for the bonded portion.
Since deterioration due to moisture absorption or corrosion is less likely to occur, glass has an advantage that it can be used for a not hermetically sealed portion (that is, outer surface of the lens cap 20).
Even when light not passing through the center of the lens impinges on the low melting point glass portion, the glass has an advantage that the amount of reflected light is small. In contrast, since the melted solder has a smooth surface, the influence of reflected light is greater than that of the glass.

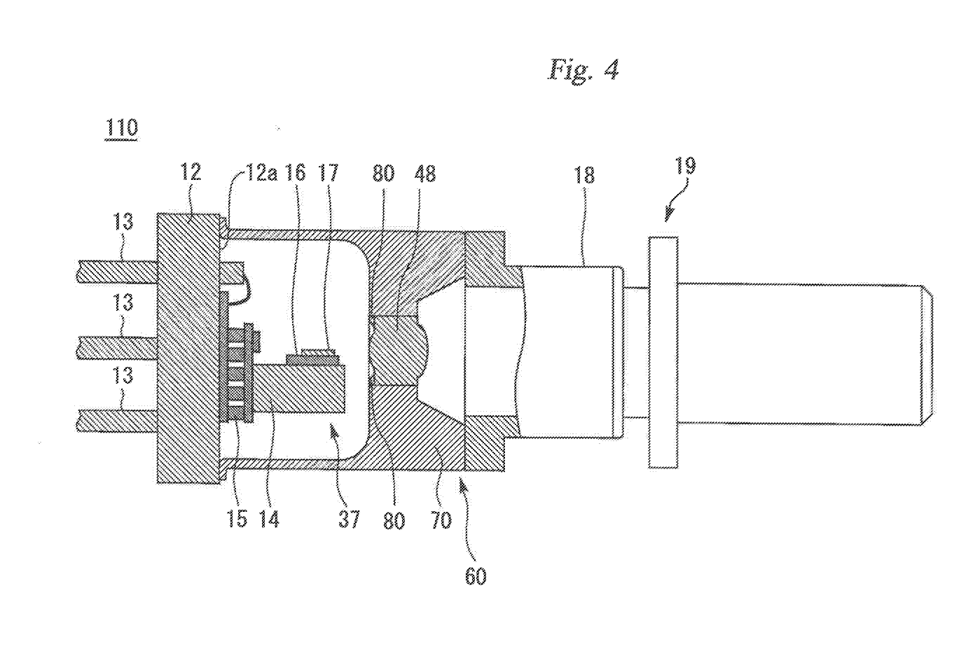

FIG. 3 is a diagram illustrating an optical module lens cap 60 according to a modification of the first embodiment of the present invention. FIG. 4 is a cross-sectional view illustrating an optical module 110 according to the modification of the first embodiment of the present invention. The lens cap 60 is different from the lens cap 20 in the position at which the low melting point glass layer is provided. A low melting point glass layer 80 is continuously provided from the surface of the lens 48 on the undersurface 31b side and the inner surface of the lens mounting hole 31d in the cover portion 31. Since the cavity 37 which is an inner space of the cylindrical portion 32 is hermetically sealed, the low melting point glass layer 80 can be provided in that hermetically sealed space.

### Second Embodiment

An optical module according to a second embodiment of the present invention is the same as the optical module 10 except in that the lens cap 20 is replaced by a lens cap 120. Therefore, components identical or equivalent to those of the first embodiment will be assigned the same reference numerals and description will focus on differences from the first embodiment and description of common items will be simplified or omitted.

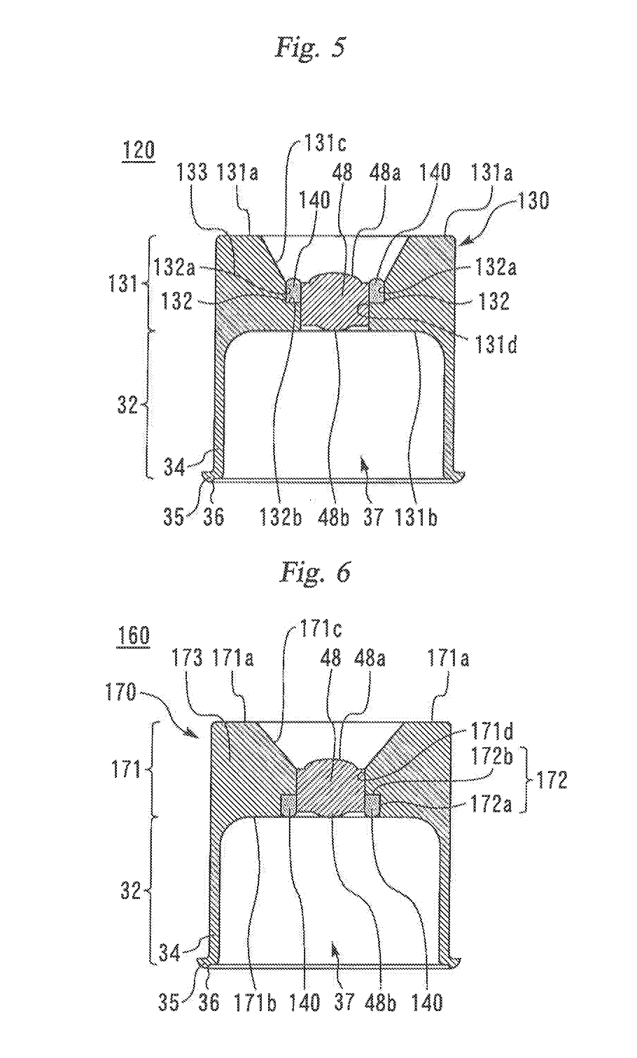

FIG. 5 is a cross-sectional view illustrating the optical module lens cap 120 according to the second embodiment of the present invention. The lens cap 120 is formed of the same material as that of the lens cap 20 and has substantially the same shape. However, the lens cap 120 is different from the lens cap 20 in that a barrel 130 thereof is provided with a groove 132.

The barrel 130 is provided with the cylindrical portion 32 like the barrel 30 according to the first embodiment and a cover portion 131 is provided at one end of this cylindrical portion 32. The cover portion 131 is provided with a thick-walled portion 133 and lens mounting holes 131c and 131d provided at a center of this thick-walled portion 133. The cover portion 131 is provided with mutually opposed top surface 131a and undersurface 131b, and the undersurface 131b faces an inside of the cylindrical portion 32. The lens mounting hole 131d is a circular hole having a certain diameter and the lens mounting hole 131c is a hole provided so as to gradually increase in diameter from one end of the lens mounting hole 131d to the top surface 131a of the cover portion 131.

The lens mounting hole 131d is provided with the lens 48. The groove 132 is provided at a rim of the lens mounting hole 131d of the barrel 130. The groove 132 is provided with a side face 132a and a bottom surface 132b. The depth of the groove 132 is preferably larger than the thickness of a low melting point glass pellet within a range from 0.1 mm to half the thickness of the lens 48. The groove 132 is provided in a ring shape along the rim of the lens mounting hole 131d. The low melting point glass layer 140 is provided in this groove 132. The low melting point glass layer 140 is accommodated in this groove 132, and it is thereby possible to prevent the low melting point glass layer 140 from flowing out into an effective diameter portion of the lens 48.

FIG. 6 is a cross-sectional view illustrating an optical module lens cap 160 according to a modification of the second embodiment of the present invention. The lens cap 160 is configured by press-molding the lens 48 into a barrel 170. The material of the barrel 170 is the same as that of the barrel 30.

The barrel 170 is provided with the cylindrical portion 32 like the barrel 30 according to the first embodiment. A cover portion 171 is provided at one end of this cylindrical portion 32. The cover portion 171 is provided with a thick-walled portion 173, and lens mounting holes 171c and 171d provided at a center of this thick-walled portion 173. The cover portion 171 is provided with mutually opposed top surface 171a and undersurface 171b, and the undersurface 171b faces an inside of the cylindrical portion 32. The lens mounting hole 171d is a circular hole having a certain diameter and the lens mounting hole 171c is a hole provided so as to gradually increase in diameter from one end of the lens mounting hole 171d to the top surface 171a of the cover portion 171.

The lens cap 120 is provided such that the groove 132 is open on the top surface 131a side of the cover portion 131, whereas the lens cap 160 is provided such that a groove 172 is open on the undersurface 171b side of the cover portion 171. This is the difference between the lens cap 120 and the lens cap 160. The groove 172 is provided with a side face 172a and a bottom surface 172b. The low melting point glass layer 140 is accommodated in the groove 172, and it is thereby possible to prevent the low melting point glass layer 140 from flowing out into an effective diameter portion of the lens 48.

### Third Embodiment

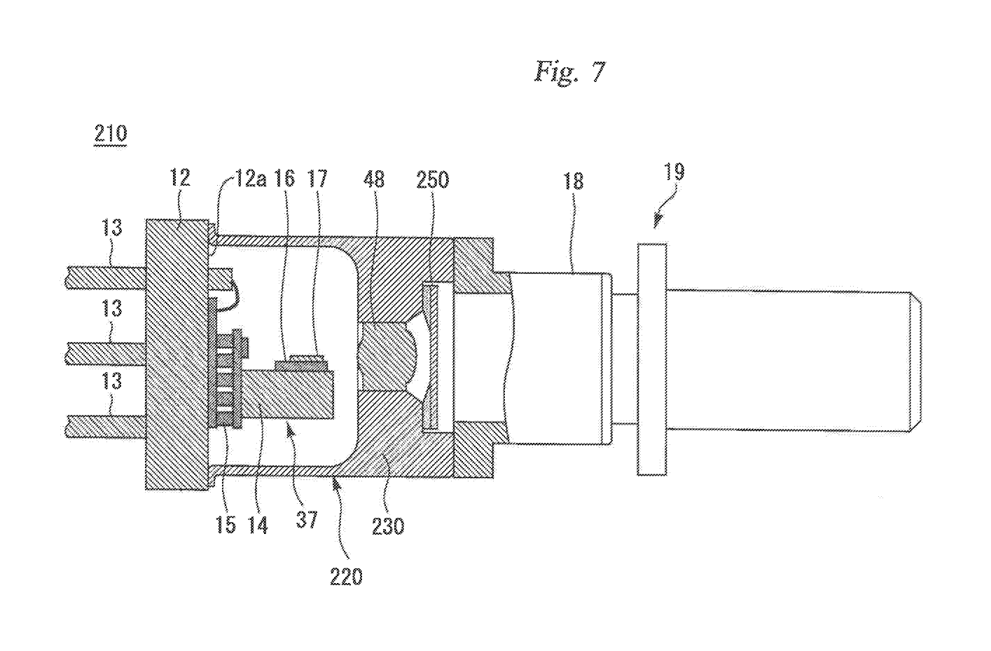

FIG. 7 is a cross-sectional view illustrating an optical module 210 according to a third embodiment of the present invention. The optical module 210 is the same as the optical module 10 except in that the lens cap 20 is replaced by a lens cap 220. Therefore, components identical or equivalent to those of the first embodiment will be assigned the same reference numerals and description will focus on differences from the first embodiment and description of common items will be simplified or omitted.

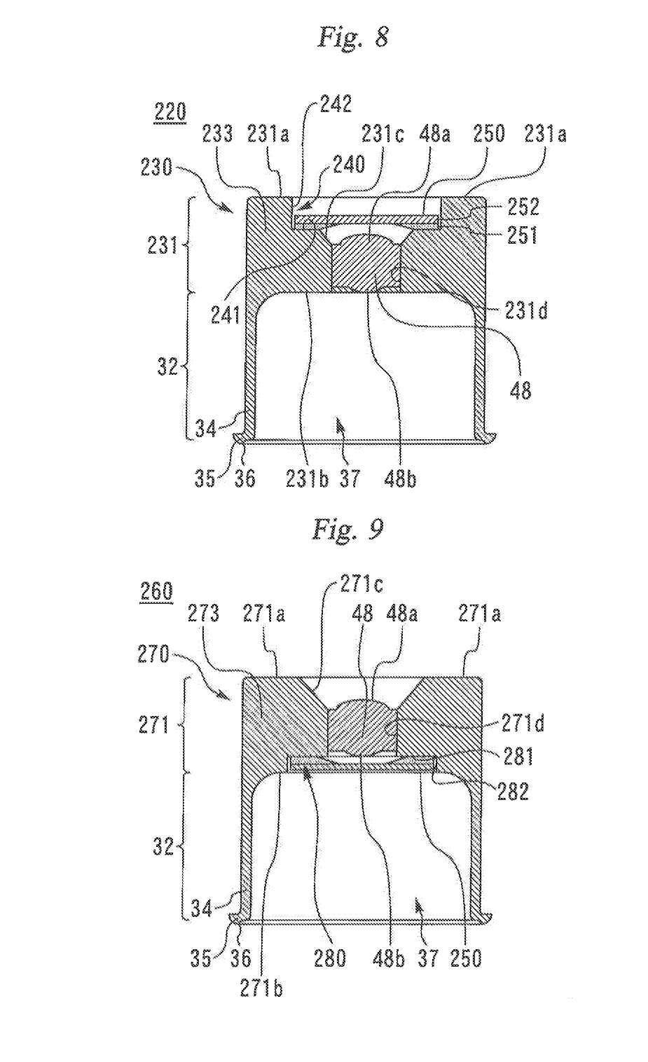

FIG. 8 is a cross-sectional view illustrating the optical module lens cap 220 according to the third embodiment of the present invention. The lens cap 220 is configured by press-molding the lens 48 into the barrel 230. The material of the barrel 230 is the same as that of the barrel 30.

The barrel 230 is provided with the cylindrical portion 32 like the barrel 30 according to the first embodiment and a cover portion 231 is provided at one end of this cylindrical portion 32. The cover portion 231 is provided with a thick-walled portion 233 and lens mounting holes 231c and 231d provided at a center of this thick-walled portion 233. The cover portion 231 is provided with mutually opposed top surface 231a and undersurface 231b, and the undersurface 231b faces an inside of the cylindrical portion 32. The lens mounting hole 231d is a circular hole having a certain diameter, and the lens mounting hole 231c is a hole provided so as to gradually increase in diameter from one end of the lens mounting hole 231d to the top surface 231a of the cover portion 231.

A concave portion 240 is provided on the top surface 231a of the cover portion 231. The diameter of this concave portion 240 is larger than the diameters of the lens mounting holes 231c and 231d. The concave portion 240 is provided with a bottom surface 241 and a side face 242, and the lens mounting hole 231c is connected at a center of the bottom surface 241.

A flat glass 250 is mounted in the concave portion 240. The flat glass 250 is made up of a glass body 252 and a low melting point glass layer 251 provided on a surface of the glass body 252. The flat glass 250 is connected to the bottom surface 241, that is, a rim of the lens mounting hole 231c in the barrel 230. This connection is realized by the low melting point glass layer 251 having a lower glass transition temperature than that of the lens glass.

Even if there is a leak path between the lens 48 and the barrel 230, airtightness can be secured by connecting the flat glass 250 via the low melting point glass layer 251.

FIG. 9 is a cross-sectional view illustrating an optical module lens cap 260 according to a modification of the third embodiment of the present invention. The lens cap 260 is configured by press-molding the lens 48 into a barrel 270. The material of the barrel 270 is the same as that of the barrel 30.

The barrel 270 is provided with the cylindrical portion 32 like the barrel 30 according to the first embodiment and a cover portion 271 is provided at one end of this cylindrical portion 32. The cover portion 271 is provided with a thick-walled portion 273, and lens mounting holes 271c and 271d provided at a center of this thick-walled portion 273. The cover portion 271 is provided with mutually opposed top surface 271a and undersurface 271b, and the undersurface 271b faces an inside of the cylindrical portion 32. The lens mounting hole 271d is a circular hole having a certain diameter and the lens mounting hole 271c is a hole provided so as to gradually increase in diameter from one end of the lens mounting hole 271d to the top surface 271a of the cover portion 271.

The lens cap 220 is provided such that the concave portion 240 is open on the top surface 231a side of the cover portion 231, whereas the lens cap 260 is provided such that a concave portion 280 is open on the undersurface 271b side of the cover portion 271. This is the difference between the lens cap 220 and the lens cap 260.

The concave portion 280 is provided on the undersurface 271b of the cover portion 271. The diameter of this concave portion 280 is larger than the diameters of the lens mounting holes 271c and 271d. The concave portion 280 is provided with a bottom surface 281 and a side face 282 and the lens mounting hole 271d is connected at a center of the bottom surface 281.

A flat glass 250 is mounted in the concave portion 280. Even if there is a leak path between the lens 48 and the barrel 270, airtightness can be secured by connecting the flat glass 250 via the low melting point glass layer 251.

The features and advantages of the present invention may be summarized as follows. The present invention closes leak paths that reduce airtightness, and can thereby prevent deterioration of airtightness even when the press-molded lens has a larger linear expansion coefficient than that of the barrel.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2013-201546, filed on Sep. 27, 2013 including specification, claims, drawings and summary, on which the Convention priority of the present application is based, is incorporated herein by reference in its entirety.

1-5. (canceled)

6. An optical module comprising:
a barrel including a cylindrical portion and a cover portion located at a first end of the cylindrical portion, wherein
the cover portion includes a lens mounting hole,
a second end of the cylindrical portion is open, and
the barrel is a material having a first linear expansion coefficient;
a lens of a lens glass having a second linear expansion coefficient that is larger than the first linear expansion coefficient and press-molded into the lens mounting hole;
a flat glass located at a rim of the lens mounting hole of the barrel and connected via a glass layer having a lower glass transition temperature than the lens glass; and
a stem including a top surface and an optical element located on the top surface, wherein
the optical element is covered by the barrel, and
the second end of the cylindrical portion of the barrel is bonded to the top surface.

7. The optical module according to claim 6, wherein the glass layer is a low melting point glass.

8. The optical module according to claim 6, wherein the second linear expansion coefficient is at least 6.5×10⁻⁶ [1/K].

9. The optical module according to claim 6, wherein the barrel is Kovar or Fe-42Ni.

10-11. (canceled)

12. An optical module lens cap comprising:
a barrel including a cylindrical portion and a cover portion located at a first end of the cylindrical portion, wherein
the cover portion includes a lens mounting hole,
a second end of the cylindrical portion is open, and
the barrel is a material having a first linear expansion coefficient;
a lens of a lens glass having a second linear expansion coefficient that is larger than the first linear expansion coefficient and press-molded into the lens mounting hole; and
a flat glass located at a rim of the lens mounting hole of the barrel and connected via a glass layer having a lower glass transition temperature than the lens glass.
